(19) United States
(12) Patent Application Publication
(10) Pub. No.: US 2009/0224369 A1
(43) Pub. Date: Sep. 10, 2009

(54) IC Substrate and Method of Manufacture of IC Substrate

(76) Inventors: Harold Samuel Gamble, Dromore (GB); Brian Mervyn Armstrong, Belfast (GB); David William McNeil, Belfast (GB); Neil Samuel John Mitchell, Newry (GB)

Correspondence Address: CHOATE, HALL & STEWART LLP, TWO INTERNATIONAL PLACE, BOSTON, MA, 02110, US

(21) Appl. No.: 12/305,799

(22) PCT Filed: Jun. 19, 2007
(86) PCT No.: PCT/GB2007/002281

§ 371 Date: Mar. 12, 2009

(30) Foreign Application Priority Data
Jun. 19, 2006 (GB) 0612093.5

(51) Int. Cl. H01L 29/12; H01L 21/18; H01L 29/06

(52) U.S. Cl. 257/616; 438/455; 257/632; 257/E29.068; 257/E21.085; 257/E29.007

(57) ABSTRACT

An integrated circuit (IC) substrate (32) comprising a germanium layer (26), an aluminium oxide layer (22), and an interfacial layer (28) provided on the germanium layer between the germanium layer and the aluminium oxide layer, which interfacial layer provides control of electrical properties at an interface between the germanium layer and the interfacial layer. The electrical properties may comprise charge carrier trap density, and the interfacial layer may provide control of the charge carrier trap density to minimise the trap density. The interfacial layer is used to ensure an intimate, high-quality germanium layer—interfacial layer interface. A method manufacturing an IC substrate is also provided, along with a gallium arsenide circuit integrated in a system-on-chip (SOC) comprising an IC substrate, and a germanium electronic circuit in combination with a gallium arsenide circuit, integrated in a system-on-chip—(SOC), comprising an IC substrate.

The present invention relates to an integrated circuit (IC) substrate, and to a method of manufacture therefor.

An “IC substrate” in this context is a material upon which a circuit forming any semiconductor device can be constructed by techniques such as one or more of doping (by diffusion or ion implantation), etching or deposition of materials. An IC substrate may include materials of a single crystal formation, as well as materials that comprise a handle portion with an active layer and/or a buried oxide layer.

One of the main driving forces behind the future development of integrated circuits is improved performance requirements, namely the desire to have faster and smaller components that have minimal power consumption. This has led to research into the production of strained silicon layers, in which the spacing between atoms of the silicon's lattice structure is increased. The strained silicon layers are produced by epitaxial silicon growth on virtual substrates. These virtual substrates consist of relaxed silicon germanium (SiGe or Si₁₋ₓGeₓ in general) layers grown on silicon substrates. The amount of strain in the silicon layers is governed by the percentage of germanium in the virtual substrate surface layers. As a result of the greater spacing between the atoms in the lattice, strained silicon has a higher carrier mobility than relaxed (unstrained) silicon and therefore enhances the operating frequency of transistors.

As desired device dimensions of MOSTs are reduced it is necessary to use a high-k dielectric to form the gate dielectric. These high-k dielectrics have to be deposited, thus nullifying the long standing advantage of silicon in having a stable native oxide. This weakening of the case for silicon provides opportunity for other semiconductor materials, which do not have a stable native oxide, but which do have intrinsically higher carrier mobilities e.g. Ge.

Parasitic capacitances which decrease circuit operating speed can be reduced by using silicon on insulator (SOI) substrates. SOI facilitates a simpler CMOS technology with better device isolation, increased packing density, increased radiation hardness and eliminates latch up. In common terminology the insulator is understood to be an oxidised silicon wafer.

Researchers are therefore investigating the transfer of strained silicon layers from the virtual substrates to oxidised silicon wafers to produce strained silicon on insulator (sSOI) substrates. A combination of Smart-cut (or ion-cut) and BESOI technologies are being employed to achieve sSOI. It has been suggested (for example by the ITRS (International Technology Roadmap for Semiconductors)) to move towards ultra thin strained Si₁₋ₓGeₓ layers on insulator and finally to germanium layers on insulator (GeOI). Germanium on insulator (GeOI) is thought of as desirable because the mobility of electrons and of holes is greater than that in silicon. Thus if MOS transistors could be fabricated in germanium they could operate faster than MOS transistors in silicon. Devices fabricated in a semiconductor on insulator will have less leakage current and less parasitic capacitance than a device fabricated in the bulk semiconductor, hence germanium on insulator.

The IRTS is mainly aimed at the high density, high speed digital market, where there is no requirement for rf analogue passive components such as inductors and transmission lines. Thus little or no attention has been taken of electromagnetic losses in the silicon handle wafers. The present operating frequencies are not high enough for this to be a significant problem except for mixed signal circuits. There has been some concern with regard to removing heat from devices on SOI substrates. The approach being considered is to replace the buried silicon dioxide layer with a more thermally conducting dielectric such as alumina or aluminium nitride.

GeOI substrates can be used for high frequency applications, but the higher frequencies exacerbate the problem of hot spots developing. Furthermore, the packing density is higher, the junction leakage current is higher and the thermal conductivity considerably lower.

In CMOS digital circuits, power is dissipated by charging and discharging the intrinsic and parasitic capacitances. Thus the higher the frequency the more power is dissipated. The maximum packing density possible with SOI will likely be the same for GeOI, which as stated above will be greater than the present state-of-art.

The speed performance of a device is very dependent on the mobility of the charge carriers. In CMOS circuits both p-channel and n-channel devices are used. The carriers in p-channel are holes and the carriers in n-channel are electrons. The mobility of electrons in silicon is about three times that for holes. In germanium both the electron and hole mobility are higher than in silicon and the difference between them is smaller. Thus CMOS circuits with similar dimensions will operate faster in germanium than in silicon.

While the main reason germanium has not been dominant before is due to the limitations of its native oxide, germanium dioxide, it also has a smaller energy band gap than silicon. This smaller band gap means that for a given junction area the reverse biased leakage current for a germanium diode is higher than for a silicon diode. Thus the power consumption of the circuit will be higher.

In GeOI and SOI the junction area is only that of the sidewalls (i.e. perimeter×layer thickness) and so for GeOI an ultra thin germanium layer should be employed. Nevertheless the leakage current will be higher for germanium circuits. The thermal conductivity of germanium is considerably less than that of silicon, thus the heat will not flow rapidly in the germanium layer giving rise to greater intensity hot spots. Combining the increased leakage currents and the higher operating frequency with the lower thermal conductivity of germanium the hot spot problem of GeOI will be greater than for SOI. It is thus necessary to consider alternative structures for germanium ICs.

Another of the main driving forces behind the future development of integrated circuits is the convergence of functions to provide a System-On-a Chip (SOC). However, one of the main drawbacks of standard SOI substrates is that the buried silicon dioxide layer (BOX) is a good thermal insulator. Thus, the higher packing density of circuit components leads to increased power dissipation. This problem is further exacerbated with the increasing operating speeds. It is thus becoming critical to reduce the impact of hot spots on device performance.

For radio frequency (rf) SOCs high resistivity substrates can be used to improve the performance of passive components such as inductors, coplanar wave guides etc. and to reduce cross-talk. For these reasons many rf designers have preferred to use silicon-on-sapphire (SOS) substrates. However, so far no fully integrated rf and digital circuits have been reported.

The original silicon on sapphire (SOS) technology offered the same advantages as (SOI), but the quality of the silicon layer was inferior and the substrates required special processing. Recently the quality of the silicon layer has been greatly improved by the Double Solid Phase Epitaxial process. Excellent quality SOS is also available through bonding silicon technology. In addition SOS provides reduced self-heating effects due to the higher thermal conductivity of 0.46 W/cm K for sapphire compared to 0.014 W/cm K for silicon dioxide. Sapphire also has excellent dielectric properties with a loss tangent of <0.0001 at 3 GHz making it an excellent substrate for passive elements such as transmission lines and inductors at microwave frequencies. It is to be noted that existing SOS substrates produced by epitaxial growth rely on the use of single crystal sapphire.

The small energy band gap E_{g} of germanium (Ge) and the related high drain-source leakage current require the use of ultra-thin body (UTB) GeOI substrates and fully depleted (FD) MOSTs. The reduced body effect, reduced kink effect and near ideal transconductance to current ratio (gₘ/I_{d}) of these FD MOSTs make this technology promising for rf circuits. However, front-back gate coupling effects may cause 1/f noise behaviour.

Taking into account the above considerations, there is a need for a new IC substrate that can be used for the formation of high performance circuitry that can be implemented in an SOC. There is also a need for an IC substrate that can be used for the formation of high frequency circuitry, and also that can be operated at varying temperatures, in particular for low temperatures.

According to a first aspect of the present invention there is provided an integrated circuit (IC) substrate comprising a germanium layer, an aluminium oxide layer, and an interracial layer provided on the germanium layer between the germanium layer and the aluminium oxide layer, which interracial layer provides control of electrical properties at an interface between the germanium layer and the interfacial layer.

The electrical properties may comprise charge carrier trap density, and the interfacial layer may provide control of the charge carrier trap density to minimise the trap density. The interfacial layer is used to ensure an intimate, high-quality germanium layer—interfacial layer interface.

The interfacial layer may be provided on a backside surface of the germanium layer. The interfacial layer may provide control of electrical properties of the interface between the backside surface of the germanium layer and the interfacial layer.

The interfacial layer may comprise a dielectric material. The dielectric material may be a high k dielectric material. A ‘high-k dielectric material’ is understood in the context of this invention to be any material that has a dielectric constant equal to or higher than that of SiO₂. The interfacial layer may comprise any of Ge₂N₂O, Al₂O₃, SiO₂, HfO₂, or other suitable dielectric material.

The germanium layer may comprise a thin germanium layer, typically greater than or equal to 3 nm thick. The germanium layer may comprise a thick germanium layer, typically in the region of 1 to 100 μm thick.

The aluminium oxide layer may comprise sapphire. The aluminium oxide layer will then comprise a single crystal. The aluminium oxide layer may comprise alumina. The aluminium oxide layer may then be polycrystalline. The aluminium oxide layer may act as a handle layer.

The IC substrate may further comprise at least one intermediate layer, provided between the interfacial layer and the aluminium oxide layer. The or each intermediate layer may provide a bond between the interfacial layer and the aluminium oxide layer. The or each or some of the intermediate layers may comprise any of amorphous aluminium oxide, polycrystalline aluminium oxide, silicon dioxide, polysilicon, amorphous silicon, aluminium nitride, or other suitable bondable material.

The IC substrate may further comprise at least one barrier layer. A barrier layer may be provided on the aluminium oxide layer between the interfacial layer and the aluminium oxide layer. The barrier layer may provide a barrier reducing out-diffusion of impurities from the aluminium oxide layer. The barrier layer may comprise any of Si₃N₄, Al₂O₃, AlN. A barrier layer may be particularly advantageous when the aluminium oxide layer comprises alumina.

According to a second aspect of the invention, there is provided a method of manufacturing an IC substrate according to the first aspect of the invention, comprising the steps of providing the interfacial layer on the germanium layer, and bonding the aluminium oxide layer to the interfacial layer such that the interfacial layer is between the germanium layer and the aluminium oxide layer.

The interfacial layer may be provided on the germanium layer by growing the interfacial layer on the germanium layer. The interfacial layer may be provided on the germanium layer by depositing the interfacial layer on the germanium layer. The interfacial layer may comprise Al₂O₃, deposited by reactive sputtering, CVD or ALD, or Ge₂N₂O thermally grown. The interfacial layer may be provided on a backside surface of the germanium layer. The interfacial layer may be annealed prior to bonding of the aluminium oxide layer thereto. The interfacial layer may be polished prior to bonding of the aluminium oxide layer thereto. The interfacial layer may undergo plasma activation prior to bonding of the aluminium oxide layer thereto.

The germanium layer may be ion implanted prior to bonding of the aluminium oxide layer to the germanium layer and interfacial layer. The germanium layer may be implanted with hydrogen prior to bonding of the aluminium oxide layer to the germanium layer and interfacial layer.

The aluminium oxide layer may comprise sapphire. The aluminium oxide layer will then comprise a single crystal. The aluminium oxide layer may comprise alumina. The aluminium oxide layer may then be polycrystalline.

The aluminium oxide layer may be annealed prior to being bonded to the interfacial layer. The aluminium oxide layer may be polished prior to being bonded to the interfacial layer. The aluminium oxide layer may undergo plasma activation prior to being bonded to the interfacial layer. The aluminium oxide layer may provide a handle layer of the IC substrate.

Bonding the aluminium oxide layer to the interfacial layer may comprise a wafer bonding process.

The method may further comprise annealing the IC substrate. This may be used to increase the strength of bonding between the interfacial layer and the aluminium oxide layer. The method may further comprise splitting the germanium layer. This may comprise ion splitting the germanium layer substantially along an area of ion implantation in the germanium layer. This may comprise splitting the germanium layer substantially along an area of implanted hydrogen in the germanium layer, The method may further comprise polishing exposed surfaces of the IC substrate.

The method may further comprise providing at least one intermediate layer between the interfacial layer and the aluminium oxide layer. An intermediate layer may be provided on the aluminium oxide layer and the intermediate layer may then be bonded to the interfacial layer. An intermediate layer may be provided on the interfacial layer and the aluminium oxide layer may then be bonded to the intermediate layer. An intermediate layer may be provided on the interfacial layer and an intermediate layer may be provided on the aluminium oxide layer, and the intermediate layers may then be bonded to each other. An intermediate layer may be provided on the interfacial layer or the aluminium oxide layer by deposition. The or each intermediate layer may be annealed prior to being bonded. The or each intermediate layer may be polished prior to being bonded. This may be used to provide a smooth bondable surface on the intermediate layer. The or each or some of the intermediate layers may comprise any of amorphous aluminium oxide, polycrystalline aluminium oxide, silicon dioxide, polysilicon, amorphous silicon, aluminium nitride, or other suitable bondable material.

The method may further comprise providing at least one barrier layer on the aluminium oxide layer and bonding the barrier layer to the interfacial layer or an intermediate layer. The barrier layer may be deposited on the aluminium oxide layer. The barrier layer may provide a barrier reducing out-diffusion of impurities from the aluminium oxide layer. The barrier layer may comprise any of Si₃N₄, Al₂O₃, AlN. A barrier layer may be particularly advantageous when the aluminium oxide layer comprises alumina.

According to a third aspect of the invention, there is provided a gallium arsenide circuit integrated in a system-on-chip (SOC) comprising an IC substrate according to the first aspect of the invention.

The gallium arsenide circuit may comprise an optical circuit. The gallium arsenide circuit may comprise an electronic circuit. A gallium arsenide layer may be epitaxially grown on the IC substrate, specifically on at least part of the germanium layer thereof.

According to a fourth aspect of the present invention there is provided a germanium electronic circuit in combination with a gallium arsenide circuit, integrated in a system-on-chip—(SOC), comprising an IC substrate according to the first aspect of the invention.

The gallium arsenide circuit may comprise an optical gallium arsenide circuit. The gallium arsenide circuit may comprise an electronic gallium arsenide circuit.

Embodiments of the invention will now be described, by way of example only, with reference to the accompanying drawings, in which:

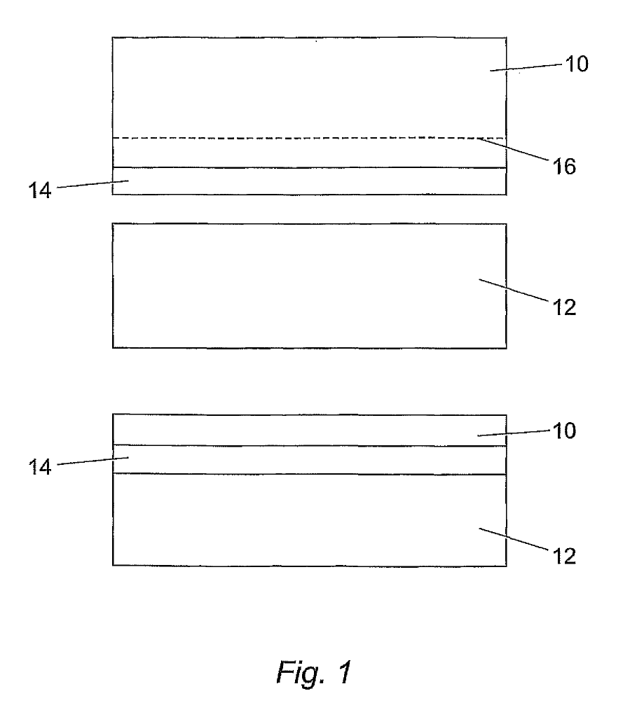

FIG. 1 shows a first method of manufacturing an IC substrate;

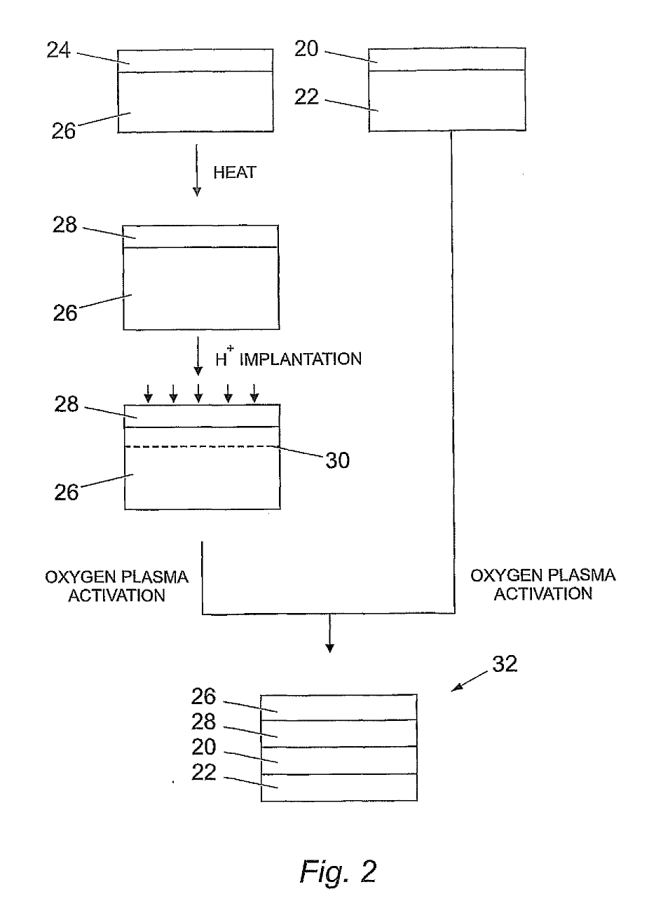

FIG. 2 shows a second method of manufacturing an IC substrate; and

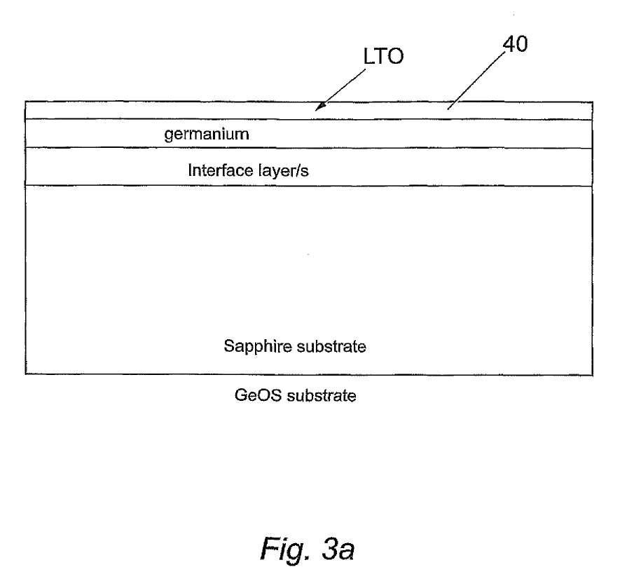

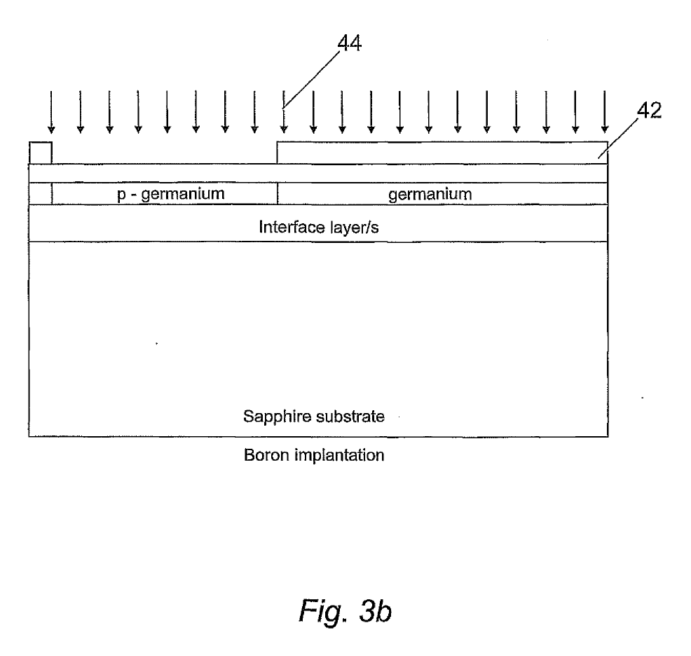

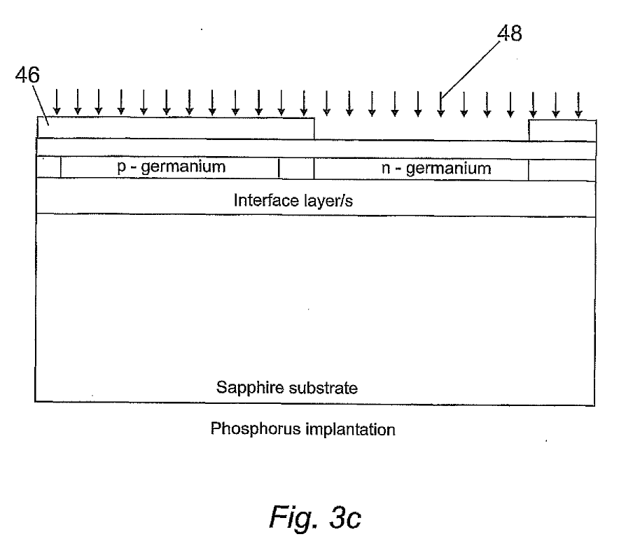

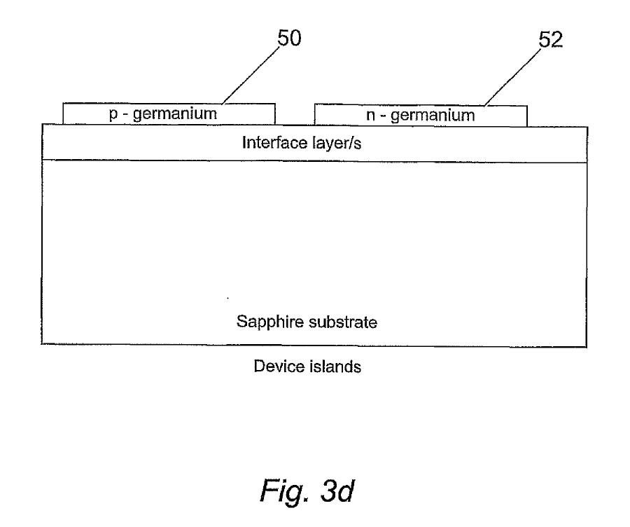

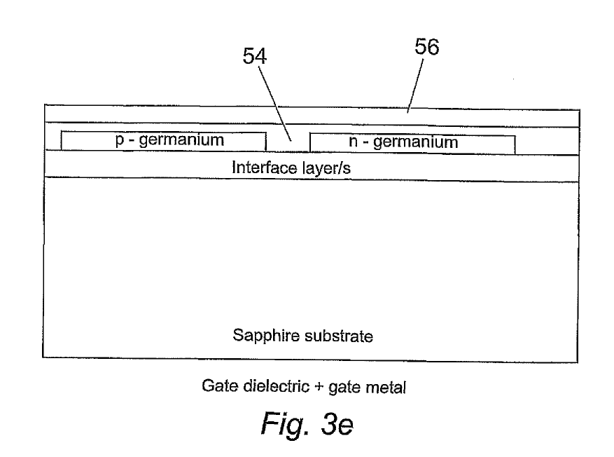

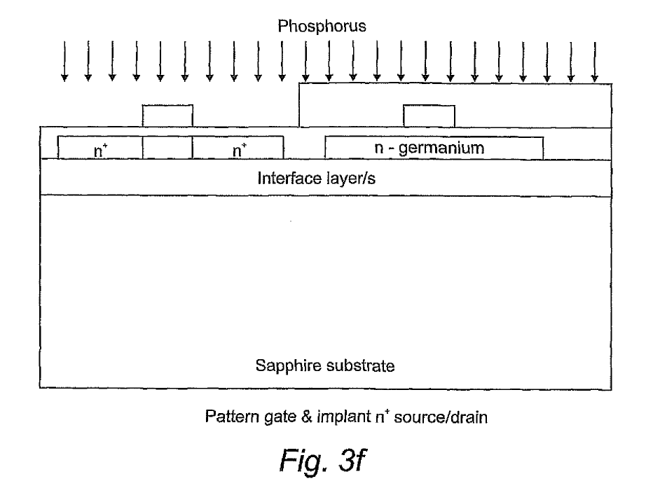

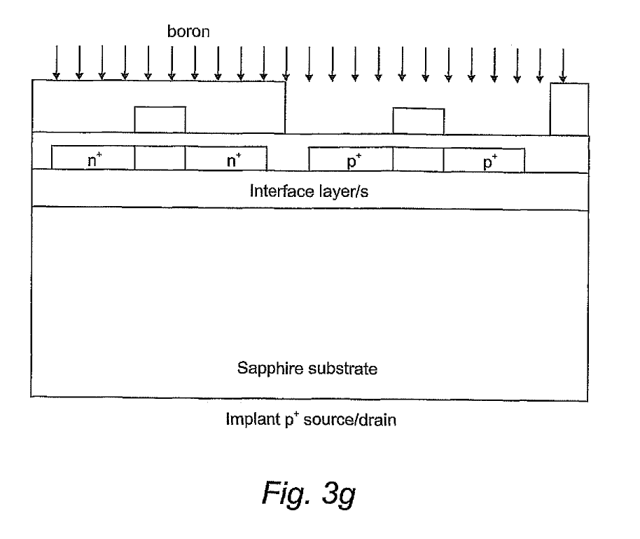

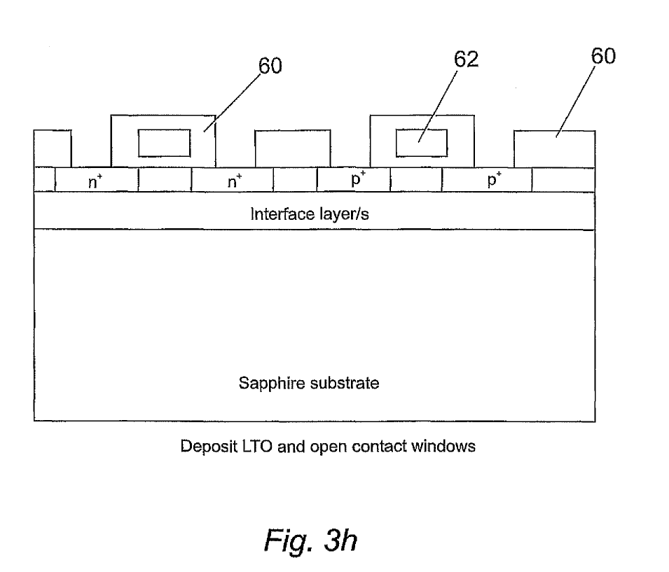

FIG. 3 shows a CMOS process using the IC substrate of FIG. 2.

FIG. 1 illustrates a first method of manufacturing an IC substrate according to the invention. This comprises first of all producing a germanium layer 10, which may be in the form of a thick germanium wafer, and producing an aluminium oxide layer 12, which may be in the form of a wafer and act as a handle. An interfacial layer 14 is then provided on a backside surface of the germanium layer 10, as shown, by growing or depositing the interfacial layer on the backside surface. The interfacial layer provides control of electrical properties at the interface between the germanium layer and the interfacial layer, and specifically reduces charge carrier trap density at the interface to a minimum. The interfacial layer comprises a dielectric material, for example any of Ge₂N₂O, Al₂O₃, SiO₂, HfO₂ or other suitable dielectric material. The interfacial layer ensures an intimate, high-quality germanium layer—interfacial layer interface with minimum trap density.

The germanium layer 10 and the interfacial layer 14 are then thermally annealed, and the exposed surface of the interfacial layer 14 is polished. The germanium layer 10 is then implanted with hydrogen, which diffuses to an implant depth illustrated at 16.

The aluminium oxide layer 12 may comprise sapphire, or may comprise alumina. The aluminium oxide layer 12 may be thermally annealed, and then may be polished. The aluminium oxide layer 12 and the exposed surface of the interfacial layer 14 then undergo plasma activation, by an oxygen plasma treatment. This improves bond strength within the IC substrate.

The aluminium oxide layer 12 is then bonded to the exposed surface of the interfacial layer 14. This may comprise a wafer bonding process. The IC substrate is then annealed at a low temperature, less than 300° C. This further improves bond strength within the IC substrate.

The germanium layer 10 is then ion split in a known manner substantially along the hydrogen implant depth 16 in the germanium layer. This forms a thin germanium layer. It will be understood that the thin germanium layer may alternatively be formed by grinding and polishing back, without the need of a hydrogen implant. Finally, exposed surfaces of the IC substrate are touch polished, to complete manufacture of the IC substrate.

FIG. 2 illustrates a second method of manufacturing an IC substrate according to the invention. This comprises first of all producing a germanium layer 26, which comprises a greater than 20 Ω-cm, polished, thick, [100] germanium wafer, and producing an aluminium oxide layer 22, which may be in the form of a wafer. A dielectric interfacial layer 28 is then provided on a backside surface of the germanium layer 26, This comprises thermally growing, at 550° C., a layer of germanium dioxide 24, twenty nm thick, on the germanium layer 26. The germanium layer 26 and the germanium dioxide layer 24 are then heated in an ammonia atmosphere at 550° C. to convert the germanium dioxide layer 24 into a Ge₂N₂O interfacial layer 28. This interfacial layer again provides control of electrical properties at the interface between the germanium layer and the interfacial layer.

The germanium layer 26 and the interfacial layer 28 are then thermally annealed, and the exposed surface of the interfacial layer 28 is polished. The germanium layer 26 is then implanted with hydrogen. A dose of 6×10¹⁶ cm⁻² hydrogen ions is implanted through the Ge₂N₂O interfacial layer 28 into the germanium layer 26. The hydrogen diffuses substantially to an implant depth illustrated at 30. It is necessary to carry out the hydrogen implant through the Ge₂N₂O interfacial layer 28, to obtain a good electrical interface between the germanium layer 26 and the Ge₂N₂O interfacial layer 28.

The aluminium oxide layer 22 may comprise sapphire, or may comprise alumina, and may again provide a handle layer. The aluminium oxide layer 22 may be thermally annealed. An intermediate layer is provided on the aluminium oxide layer 22. This comprises a twenty nm thick Al₂O₃ layer 20, which is deposited on a frontside of the aluminium oxide layer 22. The exposed surface of the intermediate layer 20 is then touch polished. This provides a smooth, bondable surface on the intermediate layer 22, which is then able to act as a bonding layer.

The exposed surface of the intermediate layer 20 and the exposed surface of the interfacial layer 28 then undergo plasma activation, by an oxygen plasma treatment. This improves bond strength within the IC substrate. The surfaces are then cleaned, without roughening, to remove any hydrocarbons etc. that may have been deposited during the hydrogen implantation.

The exposed surface of the intermediate layer 20 is then bonded to the exposed surface of the interfacial layer 28, to form an IC substrate 32. The bonding may comprise a wafer bonding process.

The germanium layer 26 is then split. The IC substrate 32 is held at a temperature of approximately 300° C., which causes the germanium layer 26 to split at the hydrogen implant depth 30. This forms a thin germanium layer. The IC substrate 32 is then annealed at approximately 800° C. This further improves bond strength within the IC substrate. Finally, exposed surfaces of the IC substrate are touch polished, to give an RMS roughness of ≦0.2 nm, to complete manufacture of the IC substrate 32.

Each of the methods given above may further comprise providing at least one barrier layer on the aluminium oxide layer. The barrier layer may be deposited on the aluminium oxide layer. The barrier layer may provide a barrier reducing out-diffusion of impurities from the aluminium oxide layer. The barrier layer may comprise any of Si₃N₄, Al₂O₃, AlN. A barrier layer may be particularly advantageous when the aluminium oxide layer comprises alumina.

It will be appreciated that the specific embodiments of the method of manufacturing an IC substrate given above, in no way limit the scope of the invention, but that they serve to illustrate possible examples of how the invention could be carried out. It will also to be appreciated that the specific values of method parameters could be varied, for different applications or for different desired device characteristics; and that some of the method steps may be omitted altogether if they are not needed for a particular case.

FIG. 3 illustrates CMOS processing of IC substrates formed by the method of FIG. 2. This processing comprises sequential steps, labelled a to h. After cleaning, the IC substrates are covered with a low temperature oxide (LTO) 40. A patterned photoresist layer 42 is used to define the boron implantation. After a low dose boron implant 44, the photoresist layer 42 is removed, and a new photoresist layer 46 is deposited and patterned. This photoresist layer 46 defines the regions for phosphorus implantation 48. After the implantation, the photoresist layer 46 is removed and a new layer deposited and patterned. This pattern is etched through the germanium layer to define the n and p germanium islands 50,52, for the p-channel and n-channel transistors respectively. An implant anneal is carried out at 600° C. before the LTO layer 40 is removed. A 40 nm layer of high-k dielectric 54 is deposited by ALD and covered with a CVD layer of WN or W 56 for the gate metal. The metal layer is patterned to provide the gate electrodes and a self-aligned mask for the source/drain implants. Patterned photoresist layers are again used to protect one type of device while the other type is being implanted (see steps f and g). After the second photoresist layer is removed, an LTO oxide layer 60 is deposited over the wafer. A 600° C. anneal is carried out to activate the implants and to reduce the interface states between the gate dielectric and the germanium. Another photoresist layer is deposited and patterned for the contact windows. After the contact windows have been etched through the LTO layer and the photoresist removed, nickel germanide 62 is formed in the windows. The contact window vias are filled with tungsten and Damascene copper interconnects formed in the normal way.

The IC substrate and associated manufacturing method of the invention provides many advantages, such as good heat removal, a low loss dielectric substrate for RF circuits, matching temperature coefficients of expansion (TCEs), very high electron mobilities at 77K for high performance applications; and low temperature processing of 3-D stacked components.

The present invention provides germanium on aluminium oxide IC substrates, which have particular suitability for very high performance circuits. For ultimate high speed performance, consideration is being given to operation of ICs at low temperatures. At 77K electron and hole mobilities in lightly doped bulk germanium exceed 20,000 cm²/V-s. For multilayer substrates to be operated at such low temperatures, it is an advantage if the layers have a similar TCE and a high thermal conductivity. Thus germanium on aluminium oxide substrates are ideally suited for such high performance low temperature operations, as germanium and aluminium oxide have similar thermal coefficients of expansion with values of 5.8×10⁻⁶ and 5×10⁻⁶ respectively. Furthermore, it is to be noted that aluminium oxide has advantages of excellent dielectric properties with a loss tangent of less than 0.0001 at 3 GHz making it an excellent substrate for passive elements such as transmission lines and inductors at microwave frequencies.

Germanium has a low melting point and does not possess a native oxide, as needed for metal oxide semiconductor transistors (MOSTs). Germanium MOSTs therefore are constructed with a grown germanium oxynitride or a deposited high-k dielectrics and employ metal gate electrodes. To maintain the stability of the gate stack the process temperatures may need to be kept below 500° C. With these tow processing temperatures, the use of a germanium on aluminium oxide substrate does not impose any additional process restrictions.

A germanium on aluminium oxide IC substrate could be used for GaAs circuits, such as optical circuits or electronic circuits. The GaAs could be epitaxially grown on the germanium on aluminium oxide IC substrate. A germanium on aluminium oxide IC substrate also offers the possibility of combining GaAs optical and/or electronic circuits with germanium electronic circuits. This has powerful application in very high performance applications in a wide variety of fields. High performance digital applications, such as microprocessors, will continue to drive the technology towards higher performance. The IRTS targets the necessary process technologies required to achieve GeOI. Relatively low temperature technology will have been established for metal MOSTs. The step towards GeOI technology will be driven by the desire for more speed and the need to remove the dissipated heat. The GeOI substrate opens up the potential of mixed optical and electronic circuits. Optical techniques could be used to transport data to and from the chip and to distribute clock signals around the chip. This could be achieved through the epitaxial growth of GaAs emitters on the germanium. For extremely fast processors the chips can be cooled to allow a further order of magnitude improvement in performance. The low temperature processes to be used for GeOI and germanium on aluminium oxide will facilitate the stacking of active layers on germanium on aluminium oxide for 3D integration.

In the world of communications the drive is toward improved systems, higher bandwidth, higher frequency, smaller size and lower cost. These systems on a chip solutions (SOC) require the processing of mixed analogue and digitals circuits. This requires the integration of passive components such as capacitors and inductors on the chip. Metal gate CMOS on germanium on aluminium oxide will provide a very high maximum frequency of oscillation fₘₐₓ, providing the capability of very high frequency analogue circuits. The technology is ideally suited to SOC where the substrates are ideal for the integration of transmission lines and inductors. Mixed semiconductor devices can be integrated on the same substrate enabling optimum devices to be used in different parts of the circuit. This makes germanium on aluminium oxide ideally suited for communications applications. The radiation hardness and the ability to operate at low temperatures make it suitable for space applications such as satellite communication systems.

1. An integrated circuit (IC) substrate comprising a germanium layer, an aluminium oxide layer, and an interfacial layer provided on the germanium layer between the germanium layer and the aluminium oxide layer, which interfacial layer provides control of electrical properties at an interface between the germanium layer and the interfacial layer.

2. The IC substrate of claim 1, in which the electrical properties comprise charge carrier trap density, and the interfacial layer provides control of the charge carrier trap density to minimise the trap density.

3. The IC substrate of claim 1 wherein the interfacial layer further comprises a dielectric material.

4. The IC substrate of claim 3, wherein the interfacial layer comprises a dielectric material selected from the following group: Ge₂N₂O, Al₂O₃, SiO₂, and HfO₂.

5. The IC substrate of claim 1, wherein the aluminium oxide layer comprises sapphire.

6. The IC substrate of claim 1, wherein the aluminium oxide layer comprises alumina.

7. The IC substrate of claim 1, further comprising at least one intermediate layer, provided between the interfacial layer and the aluminium oxide layer.

8. The IC substrate of claim 7, wherein at least one intermediate layer provides a bond between the interfacial layer and the aluminium oxide layer.

9. The IC substrate of claim 7, wherein at least one of the intermediate layers further comprises at least one of amorphous aluminium oxide, polycrystalline aluminium oxide, silicon dioxide, polysilicon, amorphous silicon, and aluminium nitride.

10. The IC substrate of claim 1, further comprising at least one barrier layer.

11. The IC substrate according to claim 10, in which a barrier layer is provided on the aluminium oxide layer between the interfacial layer and the aluminium oxide layer, and provides a barrier reducing out-diffusion of impurities from the aluminium oxide layer.

12. A method of manufacturing an IC substrate according to claim 1, comprising the steps of:
providing the interfacial layer on the germanium layer; and
bonding the aluminium oxide layer to the interfacial layer such that the interfacial layer is between the germanium layer and the aluminium oxide layer.

13. The method of claim 12, in which the germanium layer is ion implanted prior to bonding of the aluminium oxide layer to the germanium layer and interfacial layer.

14. The method of claim 12, wherein bonding the aluminium oxide layer to the interfacial layer further comprises a wafer bonding process.

15. The method of claim 12 further comprising providing at least one intermediate layer between the interfacial layer and the aluminium oxide layer.

16. The method of claim 12 further comprising providing at least one barrier layer on the aluminium oxide layer.

17. A gallium arsenide circuit integrated in a system-on-chip (SOC) comprising an IC substrate according to claim 1.

18. The gallium arsenide circuit according to claim 17, further comprising an optical circuit.

19. The gallium arsenide circuit according to claim 17, further comprising an electronic circuit.

20. A germanium electronic circuit in combination with a gallium arsenide circuit, integrated in a system-on-chip— (SOC), comprising an IC substrate according to claim 1.

21. A germanium circuit in combination with a gallium arsenide circuit according to claim 20, further comprising an optical gallium arsenide circuit.

22. A germanium circuit in combination with a gallium arsenide circuit according to claim 20, further comprising an electronic gallium arsenide circuit.

23. The IC substrate of claim 2, wherein the interfacial layer further comprises a dielectric material.

24. The IC substrate of claim 23, wherein the interfacial layer comprises a dielectric material selected from the following group: Ge₂N₂O, Al₂O₃, SiO₂, and HfO₂.

25. The IC substrate of claim 2, wherein the aluminium oxide layer comprises alumina.

26. The IC substrate of claim 3, wherein the aluminium oxide layer comprises alumina.

27. The IC substrate of claim 4, wherein the aluminium oxide layer comprises alumina.

28. The IC substrate of claim 8, wherein at least one of the intermediate layers further comprises at least one of amorphous aluminium oxide, polycrystalline aluminium oxide, silicon dioxide, polysilicon, amorphous silicon, and aluminium nitride.
